(19) United States
(12) Patent Application Publication
(10) Pub. No.: US 2013/0291523 A1
(43) Pub. Date: Nov. 7, 2013

(54) Cooling System for Diesel Emissions Fluid Injector

(71) Applicants: Viresh B. Shah, Aurora, IL (US); Paul Gerald Savich, Joliet, IL (US); Ronald J. Huber, Elburn, IL (US); Vivek Sundararaj, Peoria, IL (US)

(72) Inventors: Viresh B. Shah, Aurora, IL (US); Paul Gerald Savich, Joliet, IL (US); Ronald J. Huber, Elburn, IL (US); Vivek Sundararaj, Peoria, IL (US)

(73) Assignee: CATERPILLAR, INC., Peoria, IL (US)

(21) Appl. No.: 13/462,165

(22) Filed: May 2, 2012

(51) Int. Cl. F01N 3/10; H01L 23/467

(52) U.S. Cl. 60/287; 165/121

(57) ABSTRACT

A diesel emission fluid (DEF) injection system for a machine is disclosed. The machine includes a fan or a source of flowing air, as well as a first portion of an exhaust system coupled to an exhaust after-treatment device and a second portion of the exhaust system disposed below the exhaust after-treatment device. The DEF injection system includes a DEF line in selective communication with the first portion of the exhaust system as well as electrical components such as an electrically activated valve for injecting the DEF into the first portion of the exhaust system. To maintain the electrical components at acceptably low temperatures, a heat shield is disposed between the electrical components and the second portion of the exhaust system and an air duct is provided that communicates air from the fan or source of flowing air towards the electrical components for forced air cooling.

### TECHNICAL FIELD

This disclosure relates to selective catalytic reduction (SCR) systems that employ a liquid reductant, referred to a diesel emission fluid (DEF), by injecting the DEF into the exhaust stream upstream of a catalytic converter. More specifically, this disclosure relates to protecting the electrical components used to control the DEF injections from the ambient temperatures, which can be as high as 180° C. and which can lead to failure of the electrical components.

### BACKGROUND

Power systems for engines, factories, and power plants produce emissions that contain a variety of pollutants. These pollutants may include, for example, particulate matter (e.g., soot), nitrogen oxides (NOₓ), and sulfur compounds. Due to heightened environmental concerns, engine exhaust emission standards have become increasingly stringent. In order to comply with emission standards, engine manufactures have developed and implemented a variety of exhaust after-treatment components to reduce pollutants in exhaust gas prior to the exhaust gas being released into the atmosphere.

The exhaust after-treatment components may include, for example, a diesel particulate filter (DPF), one or more selective catalytic reduction (SCR) devices, a diesel oxidation catalyst, a heat source for regeneration of the diesel particulate filter, an exhaust gas recirculation system (EGR), a muffler, and others.

For example, SCR is a means of converting nitrogen oxides, NOₓ, with the aid of a catalyst, into diatomic nitrogen, N₂, and water, H₂O. A reductant, typically anhydrous ammonia, aqueous ammonia or urea, may be added to an exhaust stream between the DPF and SCR and the reductant is adsorbed onto a catalyst of the SCR. Carbon dioxide, CO₂, is a reaction product when urea is used as the reductant. Gaseous reductants or liquid reductants may be injected into the exhaust stream. When a liquid reductant is used, such a liquid reductant is known as diesel emission fluid, or DEF. The use of DEF has become popular because of its liquid form, which is easy to store and handle, and it has been found that the use of DEF reduces the need to rely upon EGR to meet modern emission requirements.

Packaging for some exhaust after-treatment components can be difficult given the electronic and/or electrical components needed to operate some of the exhaust after-treatment components. Specifically, the ambient temperatures and heat generated by the engine and the exhaust system can cause ambient temperatures as high as 180° C., which can lead to electronic or electrical component failure.

US2020/0186381 discloses an exhaust after-treatment system with a thermal enclosure and wherein electronic components or fluid handling components of the exhaust system is mounted outside of the thermal disclosure to protect the components from heat. In contrast, U.S. Pat. No. 5,775,450 discloses a cooling duct for an alternator of an automobile.

### SUMMARY OF THE DISCLOSURE

In one aspect, exhaust system a diesel emission fluid (DEF) injection system for a machine is disclosed. The machine may include a fan, a first portion of an exhaust system coupled to an exhaust after-treatment device and a second portion of the exhaust system. The DEF injection system may include a DEF line in selective communication with the first portion of the exhaust system. The system may also include electrical components including an electrically activated valve for injecting DEF into the first portion of the exhaust system. Further, the DEF injection system may include a heat shield disposed between the electrical components and the second portion of the exhaust system. The DEF injection system may further include an air duct having a first end directed towards the fan and a second end directed at the electrical components.

In another aspect, an exhaust after-treatment system for a diesel engine is disclosed. The diesel engine may include a fan. The exhaust after-treatment system may include a diesel particulate filter (DPF), a selective catalytic reduction (SCR) system, an exhaust system including a first portion connecting the DPF to the SCR system and a second portion. The exhaust after-treatment system may further include a DEF line in communication with the first portion of the exhaust system by an electrically activated injector. The exhaust after-treatment system may further include a heat shield disposed between the electrically activated injector and the second portion of the exhaust system. Further, the exhaust after-treatment system may include an air duct having a first end directed towards the fan and a second end directed at the electrically activated injector.

In another aspect, a method of cooling a DEF injection system for a machine is disclosed. The method may include providing the machine with a fan, providing a first portion of an exhaust system coupled to an after-treatment device and a second portion of the exhaust system. The method may further include providing the DEF injection system with a DEF line in selective communication with the first portion of the exhaust system. The DEF injection system may further include electrical components including an electrically activated valve for injecting DEF into the first portion of the exhaust system. The method may further include installing a heat shield between the electrical components and the second portion of the exhaust system and flowing air from the fan through an air duct having a first end directed towards the fan and a second end directed at the electrical components.

In yet another aspect, a diesel engine is disclosed. The diesel engine may include a fan and an exhaust after-treatment system. The exhaust after-treatment system may include a DPF, an SCR system, an exhaust system including a first portion connecting the DPF to the SCR system and a second portion. The exhaust after-treatment system may further include a DEF line in communication with the first portion of the exhaust system by an electrically activated injector and a heat shield disposed between the electrically activated injector and the second portion of the exhaust system. Further, the engine may include an air duct having a first end directed towards the fan and a second end directed at the electrically activated injector.

In any one or more of the embodiments described above, the machine may further include a wall or noise shield disposed between the fan, which may be a radiator fan and the electrical components of the DEF injector. The air duct may pass through the wall or noise shield. In a related aspect, the air duct is connected to the wall or noise shield.

In any one or more of the embodiments described above, the electrical components may include a solenoid valve. Further, the electrical components may further include at least one electrical connector.

In any one or more of the embodiments described above, the machine may further include a DPF and a SCR system wherein the first portion of the exhaust system connects the DPF to the SCR system whereby DEF may be injected downstream of the DPF and upstream of the SCR system.

### BRIEF DESCRIPTION OF THE DRAWINGS

FIG. 1 is a partial perspective view of an engine that shows, in part, the exhaust after-treatment system, the radiator fan, the air duct that passes cooling air towards the DEF injector and the DEF delivery line.

FIG. 2 is another partial perspective view of the engine shown in FIG. 1, particularly illustrating one means for connecting the air duct to the noise shield that separates the radiator and radiator fan from the exhaust after-treatment system.

FIG. 3 is another partial perspective view illustrating the spatial relationships between the DEF line, the air duct and the electrical components that drive the DEF injector (which has been removed from this view).

FIG. 4 is an enlarged and partial view of the engine as shown in FIG. 3.

FIG. 5 is a front partial perspective view of the air duct coupled to the noise shield using a bracket and U-bolt.

FIG. 6 is a rear partial perspective view of the noise shield and air duct.

FIG. 7 is a front perspective view illustrating another method for coupling the air duct to the noise shield.

FIG. 8 is a side plan view showing spatial relationship between the air duct and DEF line, with the injector apparatus removed.

FIG. 9 is a partial perspective view of the configuration illustrated in FIG. 7.

### DETAILED DESCRIPTION

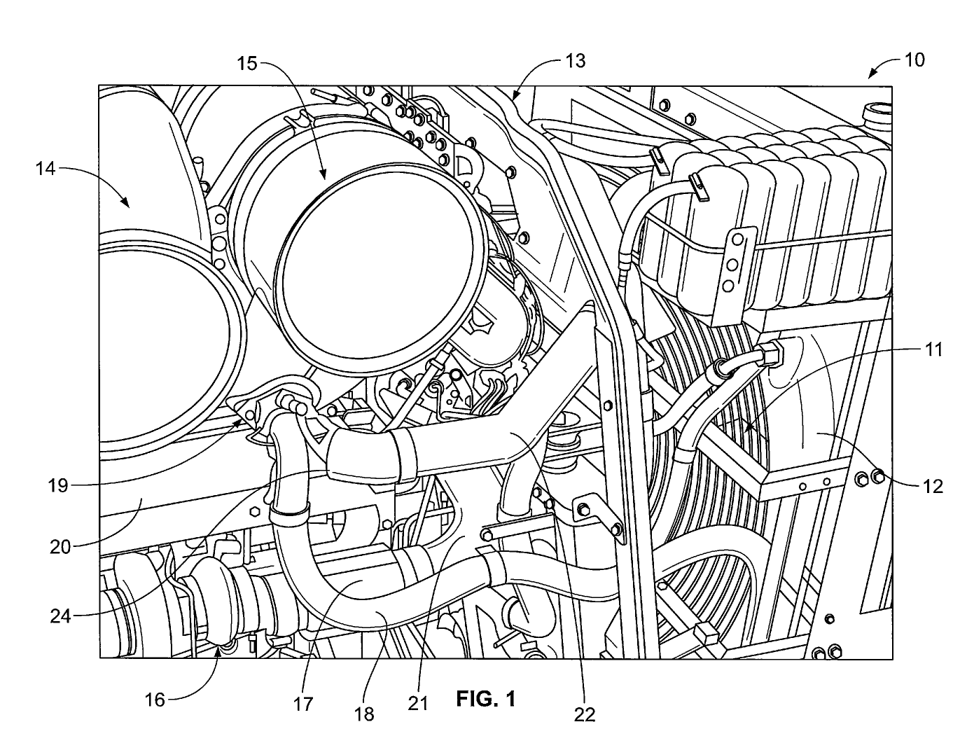

Turning to FIG. 1, a partial view of a diesel engine 10 is shown that includes a radiator fan 11 disposed within a housing 12 and on one side of a noise shield 13. The wall or noise shield 13 is optional and, as will be apparent to those skilled in the art, not necessary for practicing the principals disclosed herein. Still referring to FIG. 1, a turbocharger system 16 may be disposed below the SCR system 14 and DPF 15. The turbocharger 16 may be connected to part of an exhaust system 17. The exhaust system 17, although not shown in FIG. 1, may connect the DPF 15 to the SCR system 14. Also shown in FIG. 1 is a diesel emissions fluid (DEF) line 18 that is coupled to a DEF reservoir or supply (not shown) as well as an electrically activated injector 19. Accordingly, the DEF may be injected into the exhaust stream downstream of the DPF 15 and upstream of the SCR system 14.

One problem associated with the arrangement illustrated in FIG. 1 is the amount of heat generated by the portion of the exhaust system 17 disposed beneath the injector 19. Specifically, the reader will note that the portion of the exhaust system 17 shown in FIG. 1 also includes an elbow 21. During operation of the engine 10, surface temperatures around the elbow 21 may be in excess of 180° C. Further, air surrounding the injector 19 and electrical components associated therewith can reach about 125° C. However, a typical electrical package for an injector 19, which may include a solenoid valve and various electrical connections, should not exceed 120° C. As a result, during operation, the temperatures surrounding the injector 19 may reach 125° C., which could lead to electrical component failure.

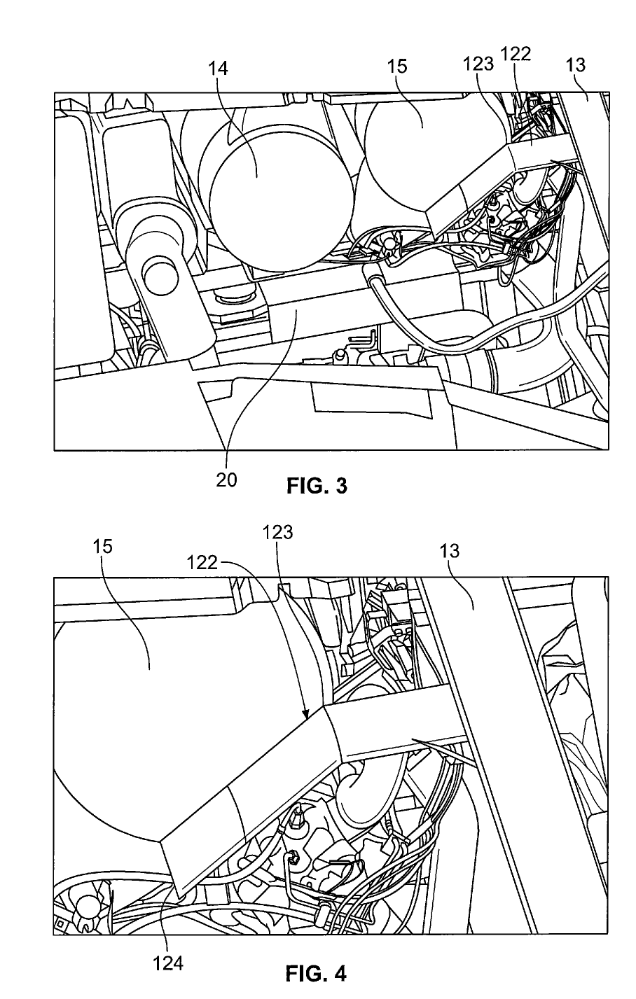

The solution to this problem is also illustrated in FIG. 1. Specifically, in one aspect an air duct 22 includes a first end 23 (see FIG. 6) directed towards the fan 11 and a second end 24 directed toward the injector 19. Air from the fan 11 blows through the air duct 22 to cool the injector 19. In another aspect, a heat shield 20 as shown in FIGS. 1 and 3 blocks radiant heat from the exhaust system 17 from reaching the injector 19 and the heat shield 20 at least partially blocks convective heat from the exhaust system 17 from reaching the injector 19.

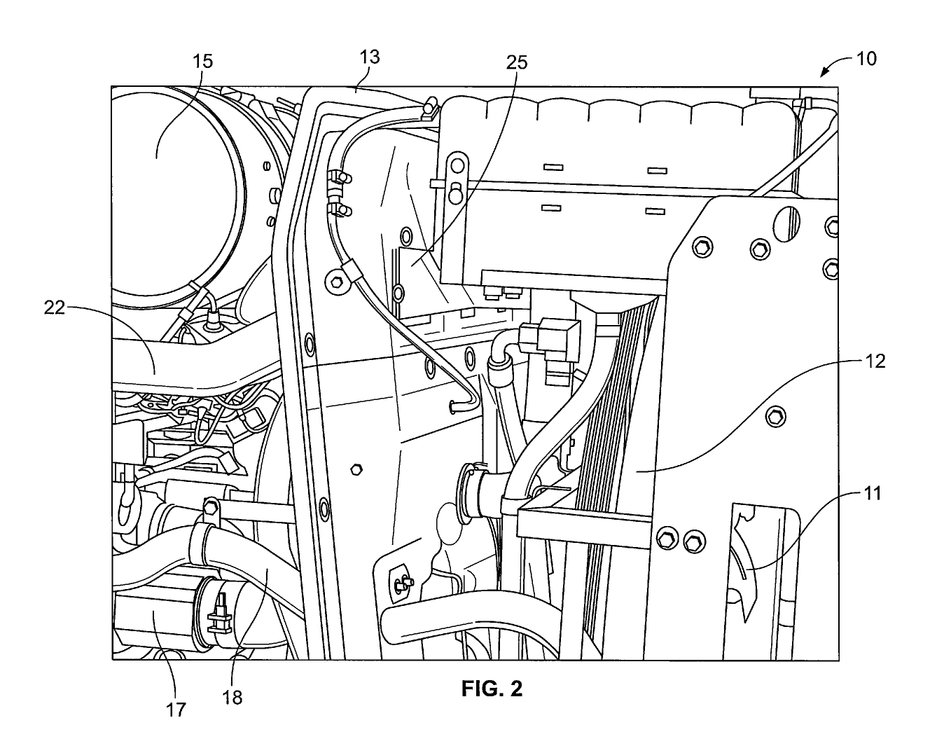

As seen in FIG. 2, the air duct 22 may be connected to the noise shield 13 using a bracket 25 that may also be shaped to draw in air for flowing through the air duct 22 to the injector 19. As a result, air flow generated by the fan 11 flows through the air duct 12 towards the injector 19, thereby blowing cool air towards the injector 19 and helping to maintain the temperature of the injector 19 and the associated electrical components at a temperature less than 120° C., even on warm days where the ambient temperature may exceed 40° C.

FIGS. 3 and 4 illustrate a different embodiment, in terms of the air duct 122. As opposed to the air duct 22 in FIGS. 1-2, the air duct 122 of FIGS. 3-4 includes a pronounced angle or elbow 123. The second end 124 of the air duct 122 is directed at a more downwardly angle towards the injector 19 (not shown in FIGS. 3-4) as opposed to the air duct 22 of FIGS. 1-2, which has a second end 24 that is directed towards the injector 19 from a more lateral position.

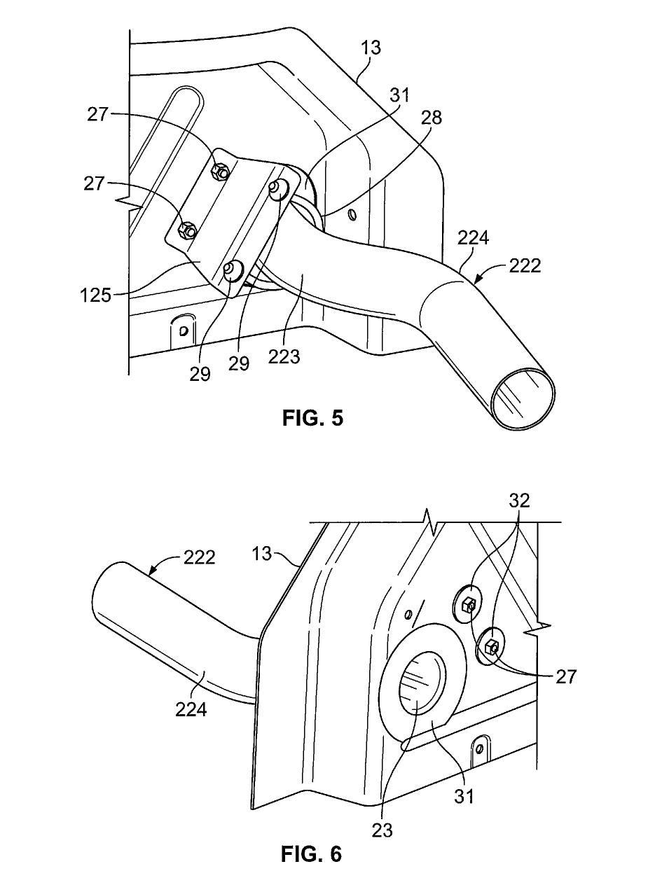

Turning to FIGS. 5-7, yet another air duct 222 is disclosed with two curved elbows 223, 224 and which is secured to the noise shield 13 with a bracket 125 that is secured to the noise shield 13 with a pair of fasteners 27 and a U-bolt 28. The U-bolt 28 is secured to the bracket 125 with a pair of fasteners 29. As shown in FIG. 6, a grommet 31 may be employed at the opening in the noise shield 13 for additional support of the first end 23 of the air duct 222. Similarly, washers 32 may be used with the fasteners 27.

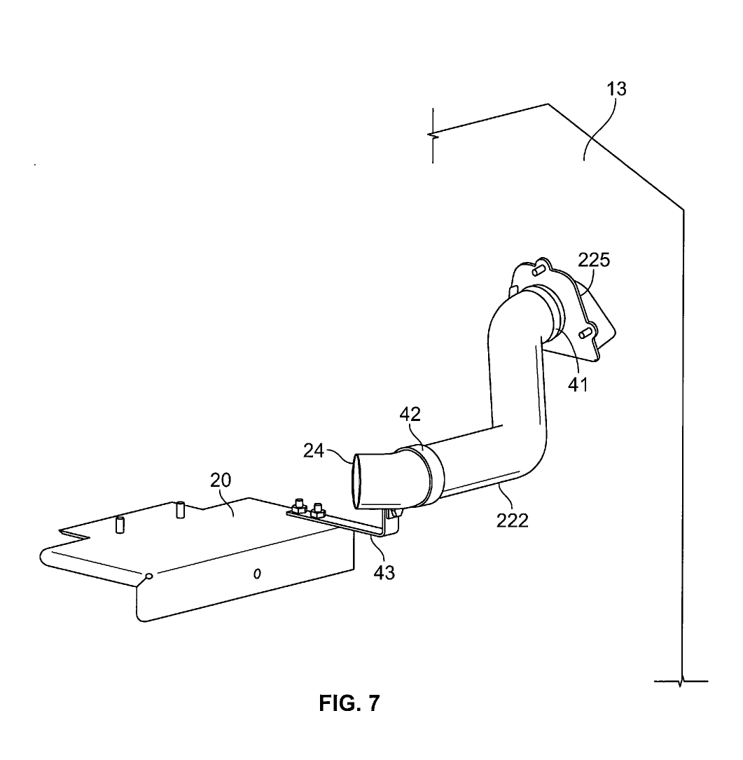

FIG. 7 illustrates another way to support the air duct 222. Specifically, a mount or bracket 225 is coupled to the noise shield 13. The air duct 222 is secured to the bracket 225 with a band 41 that is secured to the duct 222 with a bolt or fastener. A second band 42 is also used to support the second end 24 of the duct 225 as the band 42 is secured to the L-shaped bracket 43 which, in turn is secured to the heat shield 20.

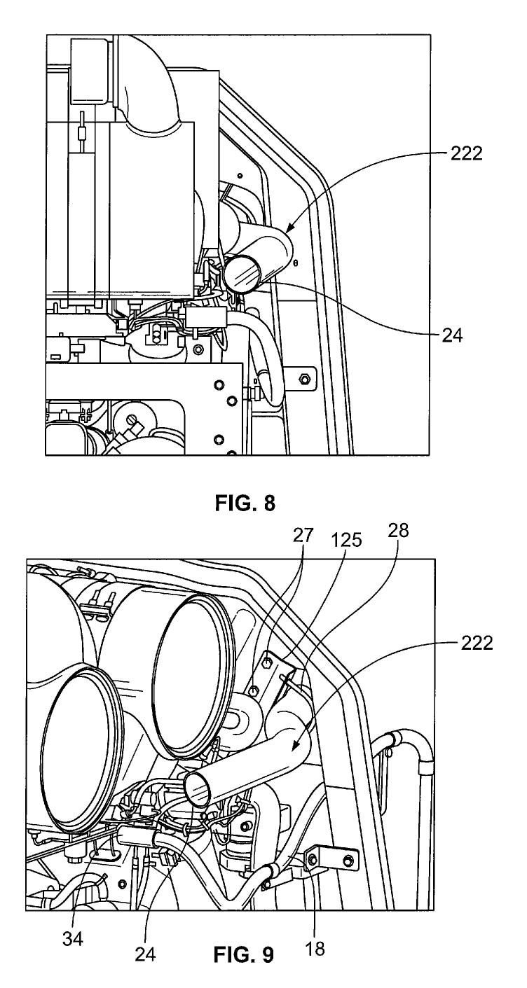

Turning to FIGS. 8-9, two additional views of the air duct 222 are provided that illustrate the position of the second end 24 of the air duct 222 relative to the distal end 34 of the DEF line 18.

Thus, a DEF injector 19 can be employed in a typical diesel engine 10 configuration wherein the exhaust after-treatment systems, such as a DPF 15 and a SCR system 14 can be disposed above a turbocharger 16 and an exhaust system 17 without the danger of overheating the injector 19. The solution provided by this disclosure may be added as a modification to existing equipment or may be original equipment on new engines.

### INDUSTRIAL APPLICABILITY

DEF injecting systems are an important part of an overall exhaust after-treatment system as the use of injected DEF upstream of the scr system 14 may reduce or eliminate the need for exhaust gas recirculation (EGR). However, many modern diesel engines are designed with the exhaust after-treatment systems disposed above the turbocharger 16 and at least one section of the exhaust system 17. As a result, an electrically-activated injector 19 used to inject the DEF into the exhaust line 18 or manifold proceeding towards the scr system 14 is exposed to substantial amounts of heat.

As noted above, the air surrounding a typical def injector 19 can reach 125° C. However, most electrical components, such as solenoid valves and electrical connections, that are used in injectors have a temperature limit requirement that is about 120° C. Hence, this disclosure solves the potential over-heating problem by providing cooler air from the preexisting radiator fan 11 to maintain the injector 19 at a temperature below 120° C., even on hot days. Further, a heat shield 20 is provided between the injector 19 and the turbocharger 16 and the portion of the exhaust system 17 extending beneath the injector 19. The heat shield 20, in combination with the air flowing through the air duct 12 both contribute to maintaining the electrical components used to inject DEF into an exhaust stream below the threshhold temperature of 120° C.

Thus, a method of cooling a DEF injection system for a diesel engine 10, or any machine for that matter, includes providing the machine with a fan 11 or a source of air flow at a temperature of less than 120° C. The machine includes a first portion of an exhaust system 17 that is coupled to the exhaust after-treatment device and a second portion disposed below the exhaust after-treatment device. A DEF injection system is in selective communication with the first portion of the exhaust system 17. The DEF injection system may further include electrical components including an electrically activated valve for injecting DEF into the first portion of the exhaust system 17 so that the DEF enters an exhaust after-treatment device, which may typically be a scr system 14. The method may further including installing a heat shield 20 between the electrical components of the DEF injection system and the second portion of the exhaust system 17 disposed below the DEF injection system and exhaust after-treatment device.

What is claimed is:

1. A diesel emission fluid (DEF) injection system for a machine, wherein the machine includes a fan, a first portion of an exhaust system coupled to an exhaust after-treatment device and a second portion of the exhaust system, disposed below the exhaust after-treatment device the DEF injection system comprising:
a DEF line in selective communication with the first portion of an exhaust system;
electrical components including an electrically activated valve for injecting DEF into the first portion of the exhaust system; and
an air duct having a first end directed towards the fan and a second end directed at the electrical components.

2. The DEF injection system of claim 1 further including a heat shield disposed between the electrical components and the second portion of the exhaust system.

3. The DEF injection system of claim 1 wherein the machine further includes a noise shield disposed between the fan and the electrical components, the air duct passing through the noise shield.

4. The DEF injection system of claim 3 wherein the air duct is connected to the noise shield.

5. The DEF injection system of claim 1 wherein the electrical components include a solenoid valve.

6. The DEF injection system of claim 5 wherein the electrical components further include at least one electrical connector.

7. The DEF injection system of claim 1 wherein the machine further includes a diesel particulate filter (DPF) and a selective catalytic reduction (SCR) system, and
the first portion of the exhaust system connecting the DPF and SCR system whereby DEF is injected downstream of the DPF and upstream of the SCR system.

8. An exhaust after-treatment system for a diesel engine, the diesel engine including a fan, the exhaust after-treatment system comprising:
a diesel particulate filter (DPF);
a selective catalytic reduction (SCR) system;
an exhaust system including a first portion connecting the DPF to the SCR system and a second portion;
a DEF line connected to the first portion of the exhaust system by an electrically activated injector; and
an air duct having a first end directed towards the fan and a second end directed at the electrically activated injector.

9. The exhaust after-treatment system of claim 8 further including a heat shield disposed between the electrically activated injector and the second portion of exhaust system.

10. The exhaust after-treatment system of claim 8 wherein the engine further includes a noise shield disposed between the radiator fan and the electrically activated injector, the air duct passing through the noise shield.

11. The exhaust after-treatment system of claim 10 wherein the air duct is coupled to the noise shield.

12. The exhaust after-treatment system of claim 8 wherein the electrically activated injector includes a solenoid valve.

13. The exhaust after-treatment system of claim 8 wherein the electrically activated injector further includes at least one electrical connector.

14. A method of cooling a DEF injection system for a machine, the method comprising:
providing the machine with a fan;
providing a first portion of an exhaust system coupled to an exhaust after-treatment device and a second portion of the exhaust system disposed below the exhaust after-treatment device;
providing the DEF injection system with a DEF line in selective communication with the first portion of an exhaust system, the DEF injection system may further include electrical components including an electrically activated valve for injecting DEF into the first portion of the exhaust system; and
flowing air from the fan through an air duct having a first end directed towards the fan and a second end directed at the electrical components.

15. The method of claim 14 further including installing a heat shield between the electrical components and the second portion of exhaust system.

16. The method of claim 14 wherein the machine further includes a noise shield disposed between the radiator fan and the electrical components, the method further including passing the air duct through the noise shield.

17. The method of claim 16 further including connecting the air duct to the noise shield.

18. The method of claim 14 wherein the electrically activated valve is a solenoid valve.

19. The method of claim 14 wherein the machine further includes a diesel particulate filter (DPF) and a selective catalytic reduction (SCR) system, and
wherein the first portion of the exhaust system connecting the DPF and SCR system, and the method further includes
injecting DEF downstream of the DPF and upstream of the SCR system.

20. A diesel engine comprising:
a fan;
an exhaust after-treatment system including
a diesel particulate filter (DPF);
a selective catalytic reduction (SCR) system;
an exhaust system including a first portion connecting the DPF to the SCR system and a second portion;
a DEF line connected to the first portion of the exhaust system by an electrically activated injector;
a heat shield disposed between the electrically activated injector and the second portion of exhaust system; and
an air duct having a first end directed towards the fan and a second end directed at the electrically activated injector.
